(19) United States
(12) Patent Application Publication
(10) Pub. No.: US 2011/0117693 A1
(43) Pub. Date: May 19, 2011

(54) DEVICE AND METHOD FOR TEMPERING OBJECTS IN A TREATMENT CHAMBER

(76) Inventors: Jorg Palm, Munchen (DE); Jorg Baumbach, Munchen (DE); Franz Karg, Munchen (DE); Martin Furfanger, Steinhoring (DE)

(21) Appl. No.: 12/991,110

(22) PCT Filed: May 8, 2009
(86) PCT No.: PCT/EP09/03301

§ 371 Date: Feb. 1, 2011

(30) Foreign Application Priority Data
May 8, 2008 (DE) 10 2008 022 784.6

(51) Int. Cl. H01L 21/26; C21D 9/00

(52) U.S. Cl. 438/97; 266/249; 257/E21.328

(57) ABSTRACT

The invention relates to a device (1) and to a method for tempering objects (2, 15). According to the invention, a temporary process box (11) is used to overcome the disadvantages of tempering processes previously known, in particular to achieve a high level of reproducibility and a high throughput during the tempering process, at the same time reducing the investment costs such that overall, the entire tempering process is carried out in a highly economical manner.

The present invention relates to a device for tempering objects according to the generic portion of claim 1 and a method for tempering objects according to the generic portion of claim 13.

Tempering methods are used with objects in diverse ways in order to fine tune specific chemical and/or physical characteristics, e.g., with thin-film solar cells.

Thus, solar modules based on chalcopyrite semiconductors (e.g., CuInSe₂, “CIS”) are among the most likely candidates for significantly more cost-effective solar power systems. Such thin-film solar modules have at least one substrate (e.g., glass, ceramic, metal foil, or plastic film), one first electrode (e.g., Mo or a metal nitride), one absorber layer (e.g., CuInSe₂ or more generally (Ag, Cu)(In, Ga, Al)(Se,S)₂), one front electrode (e.g., ZnO or SnO₂), and encapsulation and covering materials (e.g., EVA/glass or PVB/glass, where EVA stands for ethylene vinyl acetate and PVB for polyvinyl butyral) as essential components, with, in the following in each case, the chemical symbols indicated for specific elements, for example, “Mo” for molybdenum or “Se” for selenium. Additional layers, such as, alkali barrier layers between glass and Mo or buffer layers between an absorber and window layer may be used to improve efficiency and/or long-term stability. An essential additional component of a typical thin-film solar module is the integrated serial circuitry that forms a serially connected chain of individual solar cells and thus enables higher operating voltages.

The production of the semiconductor absorber layer (e.g., CIS) necessitates very high process temperatures, requires very precise control of the process atmosphere and temperature and and is, consequently, the most demanding and expensive part of the entire process sequence for the manufacture of a CIS solar module. Different methods have been used for this to date that can essentially be broken down into two categories: a) single-stage methods (e.g., co-deposition) and b) two-stage methods.

A typical characteristic of single-stage methods is the simultaneous coating of all individual elements and crystallization at a high temperature. This leads to great, sometimes contrary challenges both for process control, e.g., simultaneous control of layer composition, doping (with sodium), crystal growth, glass bending, maintenance of large-area homogeneity, and also for systems engineering, e.g., evaporator technology for Cu with a high melting point and for corrosive Se, processing under a high vacuum, homogeneity of glass heating, high throughput, and system availability, i.e., control of particle generation, etc. The realization of adequately cost-effective and reliable production processes is made more difficult thereby.

In the two-stage methods, there is a separation of coating and crystallization. After a prior coating of metal components (the so-called precursor layers, e.g., Cu and In) and, optionally, Se, near room temperature, the layer formation takes place at temperatures of much as 600° C., in one or a plurality of processing chambers separated by coating. Whereas the coating portion near room temperature can be carried out quickly and cost-effectively with conventional proven PVD processes, the second processing portion usually requires special equipment for the temperature treatment. For the manufacture of qualitatively high value chalcopyrite semiconductors, these special systems must be designed to accomplish homogeneous and rapid heating or cooling of large coated substrates, to guarantee an adequately high, controllable and reproducible partial pressure of the chalcogen elements (Se and/or S), and to ensure an oxygen and water vapor free, low particle process atmosphere. There should further be a low maintenance outlay and high system availability, and the least possible condensation of volatile components or corrosion from Se- or S-compounds should occur, and the environment should be protected from toxic process components and process materials. And finally, there should be low investment costs.

Historically, the first two-stage process with which a solar module was constructed started with sputtered precursor layers of Cu, Ga, and In on glass substrates, e.g., according to U.S. Pat. No. 4,798,660. Then, in a tube furnace, batches of these substrates were subjected to a reactive tempering and crystallization process in an atmosphere of H₂Se (in the first phase of the process) and H₂S (in the second phase) (a first form of this process was described for the first time in D. Tarrent, J. Ermer, Proc. 23rd IEEE PVSC (1993) p. 372-378). Although the first commercial chalcopyrite solar modules were manufactured with it, the homogeneity of the semiconductor layers thus produced and thus the efficiency of the solar modules must be improved for future requirements. Moreover, the transfer of this concept to mass production is possible only with difficulty.

Worldwide, the highest efficiency on large solar module surfaces has also been realized with a two-stage process, in which, however, not only Cu, Ga and In, but also Se in elemental form is deposited as a precursor layer on a substrate with PVD methods and then brought to reaction in a rapid tempering process (sometimes with the addition of an S-containing process gas). The fundamental process components are described, e.g., in EP 0 662 247 (a fundamental patent for RTP- (“rapid thermal processing”) selenization). Essential therein is a) the rapid heating of the substrate and b) a minimized processing chamber, which prevents the loss of volatile chalcogen components (Se and/or S) and their volatile reaction products with the metal components. The practical design and improvement of the concept of a reduced-volume reaction container and the construction of a manufacturing system based thereon are described, e.g., in EP 1 258 043 (selenization box) and WO 01/29901 A2 (chamber construction of the selenization system).

Although solar module production is possible with the last two concepts mentioned, the transfer of this concept to even larger chambers with higher throughput and, thus, the necessary additional cost reduction of these manufacturing systems is rendered difficult.

Consequently, the object of the present invention is to provide a device and a method for tempering objects that overcomes the above mentioned disadvantages of known furnace concepts, wherein, in particular, high reproducibility and high throughput of tempering are achieved, with, at the same time, the least possible investment costs such that, overall, the process of tempering can be realized more cost-effectively.

This object is accomplished according to the invention with a device according to claim 1 and a method according to claim 13. Advantageous improvements are specified in each case in the dependent subclaims.

Surprisingly, it turned out that the above indicated object can be accomplished if the processing space minimized compared to the chamber space of the treatment chamber is itself first produced inside the tempering chamber and not already before introduction of the object into the tempering chamber, as was described, for example, in EP 1 258 043. This is thus an only temporary encapsulation at least of the part of the object to be tempered. The temporary encapsulation during the tempering process is important not only for defined process control (e.g., maintenance of the partial pressure of the chalcogen components), but also reduces the exposure of the reaction chamber to process gases or gaseous corrosive reaction products.

Through the temporary encapsulation, for one thing, the use of closed process boxes that must be provided for each individual object or a group of objects before the introduction of the object into the tempering chamber is avoided. Thus, for one thing, costs are reduced and, for another, reproducibility is increased, since even with the most precise production of process boxes, there are conventional manufacturing tolerances and process boxes can change slightly differently over a long period of time due to the processing action, as a result of which, overall, no exactly identical processing spaces can be guaranteed. For another thing, the use of temporary encapsulation enables more effective cooling of the substrate than with process boxes, for with the use of permanent process boxes, rapid cooling of the object cannot be achieved due to reduced convection. In particular, to avoid bending of the object, both sides of the object must be cooled uniformly. With a permanent box in the cooling zone, this is possible only with low rates. With a temporary box, the top of the object and the carrier of the object or the bottom of the object can be cooled directly in the cooling zone such that clearly higher cooling rates are possible.

The device according to the invention and the method according to the invention may be used quite generally and fundamentally for the temperature treatment of objects, in particular, of large-area, coated substrates, in an inert or reactive gas atmosphere under virtually normal pressure conditions. They enable rapid tempering under a defined partial pressure of gaseous components and prevent the corrosion of the treatment chamber materials even in long-term use.

The device according to the invention for the tempering of at least one object, in particular, of a multilayer body with at least two layers, has a treatment chamber with a chamber space, at least one energy source, and a processing hood that defines a processing space in which the object can be at least partially disposed, wherein the processing hood reduces the volume of the processing space in which at least a part of the object is tempered, compared to the volume of the chamber space. The processing hood is designed at least as a cover disposed stationarily in the treatment chamber. The gas exchange between the processing space and the chamber space is, consequently, clearly reduced compared to the processing spaces designed larger or compared to processing spaces without a processing hood. It is also possible, under certain prerequisites, that with regard to the size of the processing space, essentially no gas exchange takes place between the processing space and the chamber space.

The cover may be designed either as an element disposed separately in the treatment chamber or in the form of one or a plurality of walls of the treatment chamber. In this connection, the term “stationarily” means only that the processing hood remains in the treatment chamber during successive tempering processes on different objects and is removed only for maintenance and repair measures. The processing hood may, however, be designed movably inside the treatment chamber, in particular, in continuous systems, in a direction perpendicular to the transporter direction of the object; however, it does not have to be, in other words, it suffices for the object to be disposed at a certain distance below the processing hood, because the processing space is thus reduced compared to the chamber space.

The volume of the processing space is essentially determined by the area of the object (for example, a glass substrate) or the area of the substrate carrier and height of the cover above the substrate, i.e., the distance between the top of the substrate and the bottom of the cover. The distance should be less than 50 mm, preferably less than 10 mm. In practice, a minimum distance may be required if the cover must not make contact with the object and has surface irregularities or, as, for example, a glass substrate, bends due to heating. In practice, consequently, a distance of 1 mm to 8 mm could be advantageous. An even smaller distance could be advantageous for foil substrates or very thin sheets of glass.

Preferably, the device is designed such that the distance between the cover and the object is adjustable, with the cover being preferably displaceably disposed in the treatment chamber. Thus, for one thing, differently designed processing spaces could be provided for different objects and, for another, the processing space can be adapted by phases during the tempering process.

In an advantageous embodiment, a spacer is provided to maintain a minimum distance between the cover and the object, with the at least one spacer preferably designed as a circumferential frame and, in particular, to rest on the object or a carrier for the object and thus clearly reduce the gas exchange between the processing space and the chamber space, or to essentially seal the processing space relative to the chamber space.

The spacer may also be an integral part of the carrier such that the cover rests on the frame and thus clearly reduces the gas exchange between the processing space and the chamber space.

For the present invention, a complete seal need not exist between the processing space and the chamber space. A gas exchange barrier or pressure equalization resistance must be formed between the processing space and the chamber space to prevent evaporating layer components, process gases, or process reaction gases from passing over into the chamber space in an uncontrolled amount relative to the total amount of process gases or process reaction gases. In the simplest embodiment, already with large substrates, a very small distance between the cover and the substrate or a carrier forms a gas exchange barrier that clearly reduces the escape of the volatile components from the processing space, in particular when the open path length is short (for example, with processing at near standard pressure). Of course, however, special sealing measures may be provided, such as a sealing frame, that form pressure equalization resistance to largely or completely prevent a gas exchange, even when the total pressure in the processing space is at times greater than the pressure in the chamber space. The pressure equalization resistance or the gas exchange barrier must at least be designed such that the mass loss of the chalcogen components (S, Se) from the processing space through evaporation and outward diffusion is less than 50%, preferably 20%, and optimally less than 10%. Relatively small losses can be compensated by a increased supply. Relatively large losses are also disadvantageous from the standpoint of material costs and stressing of the chamber space by the corrosive chalcogens or their compounds.

Preferably, the cover has a circumferential frame dimensioned such that the object or a carrier supporting the object can be encased on the sides, with the frame preferably displaceably disposed laterally relative to the object or the carrier (in other words, e.g., in the case of a vertical arrangement of the cover above the object, the frame can be moved outwardly past the external sides of the object or the frame). Thus, it is achieved that the distance between the cover and the surface of the object is variably adjustable, and thus the tempering process can be adjustably defined with regard to the object and its desired chemical and/or physical properties. This frame can also serve simultaneously as a spacer for relatively large objects or carriers. Instead of such a frame designed laterally displaceable past the object or its carrier, a frame can be provided that is designed as a spacer, which is designed displaceably with regard to the cover. Then, the distance between the cover and the surface of the object can also be adjustably defined despite the spacer resting essentially on the surface of the object or its carrier.

Preferably, the processing hood and the object or the carrier form a gas exchange barrier that reduces the gas exchange between the processing space and the chamber space such that the mass loss due to material components of the object evaporating off in the heating process is less than 50%, preferably less than 20%, and and is ideally below 10%.

In another preferred embodiment, the processing space that is formed by the processing hood and the object or the carrier forms pressure equalization resistance relative to the chamber space.

Furthermore, the processing hood and the object or the carrier are preferably designed such that the processing space that is formed by the processing hood and the object or the carrier is sealed essentially gas tight. This can mean that relative to the size of the processing space essentially no gas exchange occurs between the processing space and the chamber space.

In a further advantageous embodiment, the processing hood has an essentially circumferential zone that is connected with at least one gas inlet and/or gas outlet and is disposed between the processing space and the chamber space relative to a gas passage direction. By providing an overpressure or an underpressure by using an inflowing inert gas, a transfer of process gases or process reaction gases into the chamber space can be further reduced.

Advantageously, the processing hood has at least one gas inlet and/or at least one gas outlet, with the processing hood preferably having a gas sparger designed two-dimensionally. Through gas influx and discharge, the partial pressure of specific components in the process gas or process reaction gas can be adjustably defined. With the two-dimensionally designed gas sparger, the partial pressure can be adjusted particularly homogeneously. A two-dimensionally designed gas inlet is particularly recommended for processes or some process phases wherein the loss of gaseous components from the starting layer or its reaction products is not very critical, because otherwise the holes for the gas passage again increase the loss of these gaseous components or reaction products from the processing space. Advantageously, through the combination of a stationary processing hood with the gas inlet or gas outlet, it is achieved that coupling means as required and depicted in WO 01/09961 A2 are unnecessary, whereby, for one thing, the stability of the device and also, for another, the reproducibility of the tempering are improved.

The partial pressure of the gaseous components is determined, on the one hand, by the temperature and the substance amounts provided and, on the other, by the loss of gaseous components from the processing space. The total loss is determined by the open path length of the gaseous components at a given total pressure and temperature and the geometric marginal conditions, i.e., by the height of the processing space relative to the object, the size of the object, and the tightness of the processing space against a gas transfer and the chamber space. Through the selection of the process parameters as well as the dimensioning and design of the encapsulation of the object, the partial pressure of important process-relevant gaseous components can, consequently, be better controlled (e.g., the partial pressure of the chalcogen components Se and S during manufacture of CIS-solar cells). In particular, by minimizing the gas space, it can be achieved that liquid phases developing during processing can still remain in thermal equilibrium with their vapor pressure and not evaporate off completely in the very much larger volume of the reaction chamber. This invention encompasses all designs in which the gas exchange between the processing space formed by the hood and the chamber space is clearly reduced. Additional process gases (such as nitrogen, hydrogen sulfide) that are let in before or during the process, may, however, under certain circumstances, escape even in relatively large quantities from the processing space through the remaining gaps if, due to heating and tempering, the total pressure rises above the total pressure of the chamber space. A truly gas-tight design is only one possible design of those presented here. Essential to all designs according to the invention is the reduction of the loss of the layer components first partially vaporized in the heating process (e.g., Se and S). Their mass loss should be less than 20%.

Preferably, the energy source is disposed outside the reaction space and is preferably designed as a radiation source for electromagnetic radiation and, in particular, as a single radiation source or as an arrangement of a plurality of punctiform radiation sources, with the radiation source preferably provided with a reflector on the side turned away from the reaction chamber of the radiation source. The relocation of the heating elements (including the optional reflectors) to the outside permits a more rapid exchange of defective heating elements during continuous operation, enables the use of more efficient and more cost-effective reflectors that do not come in contact with the corrosive process gases, and thus also cannot corrode (e.g., metal reflectors, cooled reflectors). Moreover, under certain circumstances with the use of a large number of punctiform heating elements, tempering can be continued despite the failure of individual punctiform heating elements, if, overall, adequately homogeneous tempering of the object is ensured.

Furthermore, it is preferred that the processing hood be designed at least partially transparent to electromagnetic radiation and/or at least one wall of the treatment chamber be designed at least zone-wise at least partially transparent to electromagnetic radiation, with, preferably, segments designed at least partially transparent to electromagnetic radiation accommodated in a support frame. Then, the energy of the energy sources can act directly through thermal radiation, whereby the energy sources can be disposed either inside or outside the treatment chamber.

Advantageously, at least one wall of the treatment chamber is provided with a coating and/or lining that essentially prevents cladding of the chamber wall or action of corrosive gases and vapors thereon, with the chamber wall preferably heatably equipped such that cladding with volatile components is essentially prevented. This enables the operation of the treatment chamber for a long time essentially without maintenance periods.

Furthermore, it is preferred that the treatment chamber be designed to temper two or more objects simultaneously, whereby either a common processing hood or a dedicated processing hood for each object is provided.

Moreover, at least two treatment chambers for tempering disposed one after another in the transport direction of the object and/or at least one setup for cooling the object can be provided, whereby the cooling setup is preferably disposed in a cooling chamber independent of the treatment chamber.

Independent protection is claimed for a method for tempering at least one object, in particular a multilayer body with at least two layers, in a treatment chamber with a chamber space, in particular with the use of the device for tempering according to the invention, whereby the object is brought into the treatment chamber and exposed at least zone-wise to an energy source, whereby, in the treatment chamber, a processing space that is smaller than the chamber space is disposed at least zone-wise around the object. The processing space is formed only in the interior of the treatment chamber. In other words, no process box introducible along with the object from the outside of the treatment chamber is used, but rather, the at least partial encapsulation of the object does not occur until inside the treatment chamber and the means for encapsulation remain in the treatment chamber before the introduction of the object into and after removal of the object from the treatment chamber. Advantageously, the processing space is adapted such that the processing space is delimited physically from the chamber space by at least pressure equalization resistance.

The gas exchange between the processing space and the chamber space is clearly reduced; optionally, depending on the size of the processing space, essentially no gas exchange takes place between the processing space and the chamber space.

For this method, the use of purging gas for the chamber space and the setting of a defined pressure gradient to generate a gap counterflow purging is expedient, as they are known from WO 01/29901 A2, for which reason the relevant content of WO 01/29901 A2 is completely included by reference in the present invention. This effectively prevents a gas transfer from the processing space into the chamber space. For this, providing a buffer space surrounding the processing space is necessary, which is disposed between the chamber space and the processing space in the direction of gas passage, whereby the buffer space is connected to a gas outlet that discharges the gas directly out of the treatment chamber; this means that the gases discharged from the buffer space do not enter the chamber space.

The characteristics as well as the advantages of the present invention are explained in greater detail in the following with reference to some exemplary embodiments in conjunction with the drawings. They depict

FIG. 1 a first embodiment of the device according to the invention in cross-section,

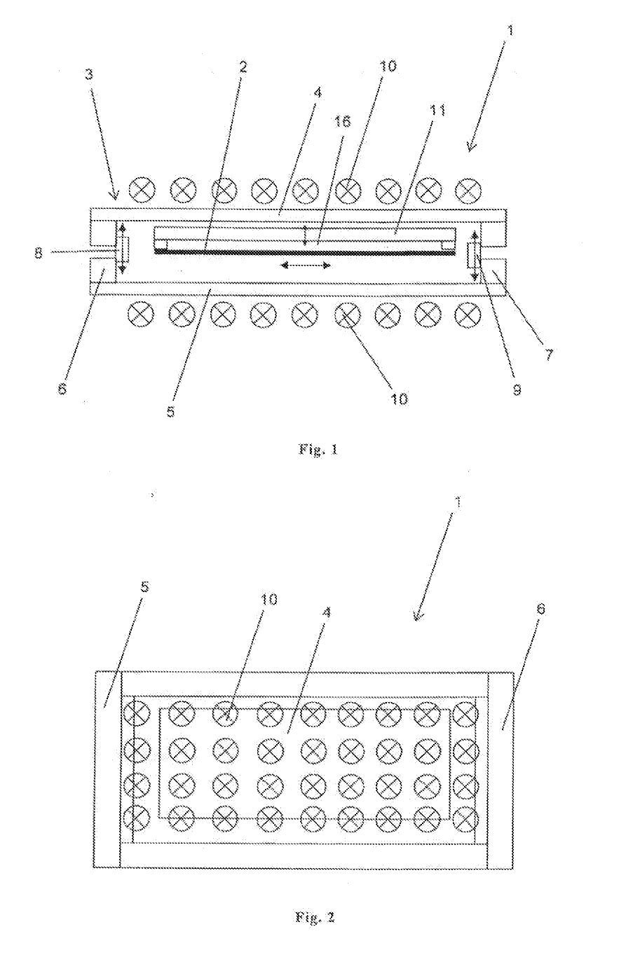

FIG. 2 the embodiment according to FIG. 1 in a top view,

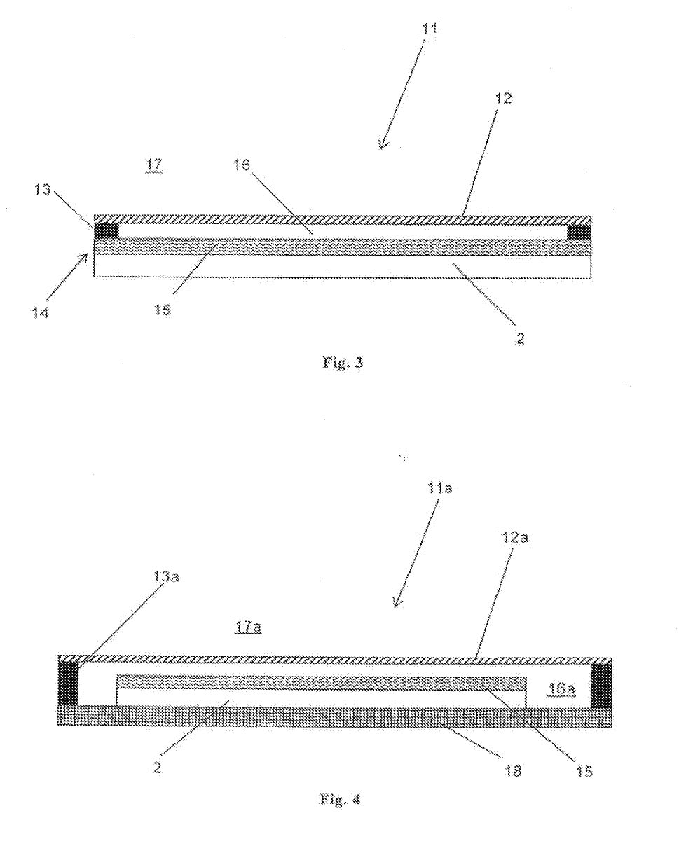

FIG. 3 the processing hood according to FIG. 1 in a detailed view,

FIG. 4 the processing hood in a first alternative embodiment,

FIG. 5 the processing hood in a second alternative embodiment,

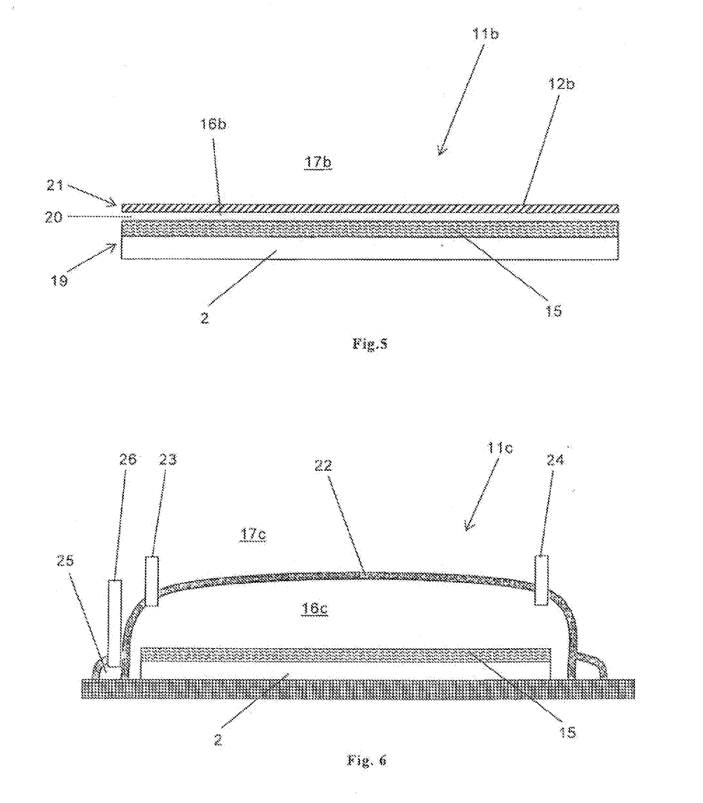

FIG. 6 the processing hood in a third alternative embodiment,

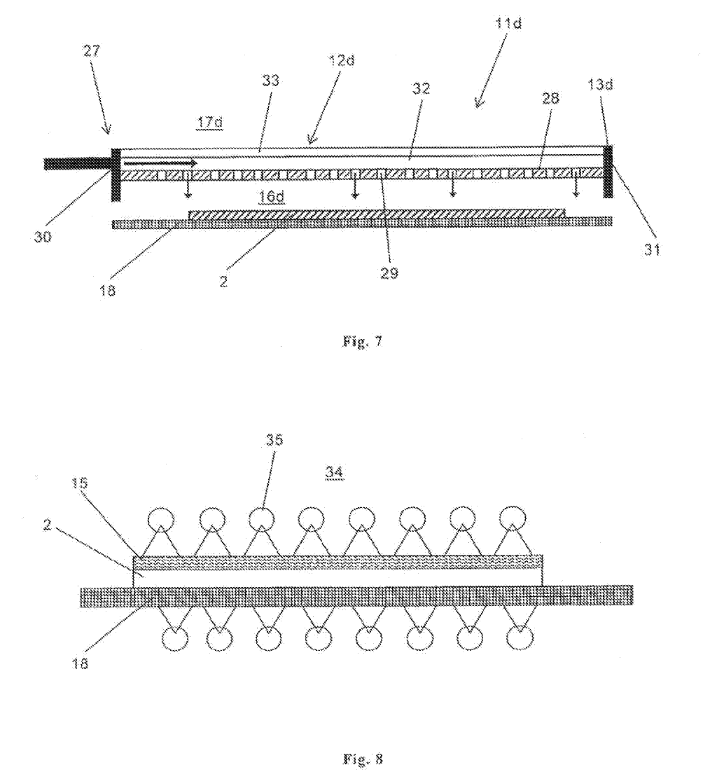

FIG. 7 the processing hood in a fourth alternative embodiment,

FIG. 8 a device according to the invention with a partial view of the cooling zone,

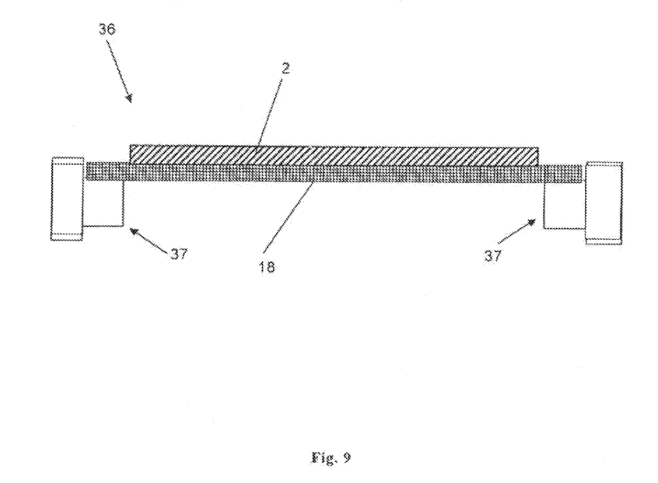

FIG. 9 the transport setup for the device according to the invention,

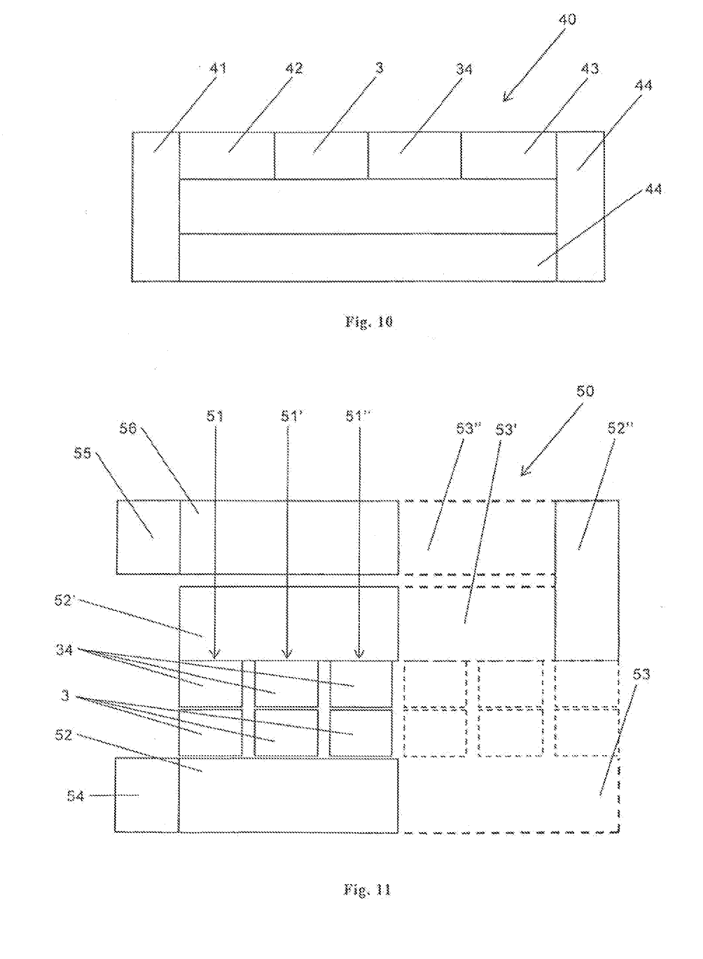

FIG. 10 the schematic view of a first overall system, into which the device according to the invention is integrated, and

FIG. 11 the schematic view of a second overall system, into which the device according to the invention is integrated.

In the following, the same or similar reference characters are used for the same or similarly designed characteristics.

FIG. 1 through 3 depict, purely schematically, the device according to the invention 1 in a first preferred embodiment that is suited to temper large-area substrates 2. It can be discerned that the device 1 has a treatment chamber 3 with chamber walls 4, 5, 6, 7 and an entry door 8 and an opposing exit door 9. To transport the substrate 2, a transport device (not shown) is provided that operates with or without a carrier for the substrate 2 and can transport the substrate 2 through the doors 8, 9 through the treatment chamber 3. Above and below the treatment chamber 3, a plurality of punctiform sources 10 for electromagnetic radiation are disposed as a matrix. For permeation of the radiation, the chamber cover 4 and the chamber floor 5 of the treatment chamber 3 are designed at least zone-wise at least partially transparent to enable homogeneous action of energy on the substrate 2.

In the interior of the treatment chamber 3, a processing hood 11 is provided, which has a cover 12 permeable or at least partially permeable to the electromagnetic radiation and a spacer 13 designed in the form of a frame that is dimensioned such that it can rest on the periphery 14 of the substrate 2 with the substrate coating 15, when the substrate 2 is positioned under the processing hood 11. The processing hood 11 is disposed vertically displaceably relative to the substrate 2 and defines a processing space 16 between itself and the substrate 2 that is largely sealed against the chamber space 17, such that during tempering, virtually no gas is transferred into the chamber space 17 with regard to the process gases and process reaction gases contained in the processing space 16. The height of the processing space 16, i.e., the distance between the cover 12 and a coated substrate 2 can be adjusted by vertical movement of the cover 12 toward the substrate 2. In principle, the vertical movement of the substrate 2 from below toward the processing hood 11 is also conceivable. The double arrows sketched in indicate the mobilities of the corresponding parts.

In a first alternative embodiment of the processing hood 11a according to FIG. 4, its cover 12a together with the spacer frame 13a is dimensioned such that the processing hood 11a with the smallest proximity comes to rest not on the substrate coating 15 of the substrate 2, but rather on the substrate carrier 18 and thus essentially seals the processing space 16a from the chamber space 17a.

In a second alternative embodiment of the processing hood 11b according to FIG. 5, it has only one cover 12b that has at least the same dimensioning as the substrate 2. For the essential sealing of the processing space 16b from the chamber space 17b, the processing space 16b has a small height relative to the lateral dimension. Thus, the gap 20 present on the periphery 19 of the substrate 2 between the substrate coating 15 and the periphery 21 of the cover 12b acts as pressure resistance or a gas exchange barrier, whereby relative to the total processing space 16b only very little gas can pass over out of this into the chamber space 17b. However, the cover 12b need not be designed parallel to the surface of the substrate 2, but can instead also have other courses, such as an arc-shaped course. This course of the inside surface of the cover 12b can be adapted appropriately for optimization of the tempering process.

In specific phases of the tempering process, the distance between the cover 12, 12a, 12b substrate in the embodiment variants according to FIG. 3 through FIG. 5 should be very small relative to the lateral dimensions of the substrate 2. The cover 12, 12a, 12b, the height of the processing space 16, 16a, 16b, and the optimum frame 13 reduce the uninhibited discharge of gaseous components from the processing space 16, 16a, 16b between the coated substrate 2 and the cover 12, 12a, 12b. The gaseous components may be process gases added before or during the process (e.g., H₂S, H₂Se, Se- or S-vapor, H₂, N₂, He, or Ar) or gaseous components and reaction products of the coated substrate. In the specific case of Cu—In—Ga—Se precursor layers, for example, Se- or S-vapor, gaseous binary selenides, N₂, H₂S, or H₂Se.

In a third alternative embodiment of the processing hood 11c according to FIG. 6, this is formed by a glass receptacle 22 that has inlet and outlet openings 23, 24 for the addition of process gas. In addition, the processing hood 11c has a circumferential channel 25 with a connector 26 that is disposed between the processing space 16c and the chamber space 17c in the gas passage direction. Here, the term “gas passage direction” means only a possible gas transfer between the processing space 16c and the chamber space 17c, which does not have to occur, but if it does occur, it is possible only via the channel 25.

Through the connector 26, the channel 25 can be suctioned in a leakproof manner on the substrate carrier 18 or the substrate 2 (not shown), when the channel is evacuated (under pressure or vacuum). Thus, an optimum gas encapsulation of the substrate between the processing hood 11c and the substrate carrier 18 is achieved, and the contamination of the chamber space 17c with process gas and and reaction gases is reduced, ideally prevented. Through the supply channel 23 in the processing hood 11c, process gas is added; and through the exhaust channel 24, the added or generated gas mixture is discharged. The efficiency of gas utilization is significantly increased through this arrangement compared to a treatment chamber 1 completely filled with process gas; and, thus, a reduction of production costs is achieved compared to prior art treatment chambers. In contrast to EP 1 258 043, here, the contamination of the chamber space is further reduced and the extent of purging of the chamber space and post-treatment technology necessary is minimized

Instead of evacuating the channel 25, it can also be set under slight overpressure by means of an inert gas that is supplied. The inert gas overflowing into the processing space 16c through any openings reduces the diffusion losses of process gas into the chamber space 17c.

The use of a partially transparent cover 12, 12a, 12b, 12c permits process control of the heating process according to EP 1 258 043 with controlled energy input from above and below into the coated glass substrate 2. When a substrate carrier, for example, a substrate carrier plate 18, is used, this can be partially transparent or completely absorptive.

The processing hood 11d can also be equipped with a two-dimensional process gas sparger 27 according to FIG. 7, wherein the processing hood 11d is depicted in a position not yet closed relative to the substrate carrier 18d. For this, the semitransparent cover 12d is implemented double walled. The bottom cover 28 contains small holes 29 for rapid uniform gas distribution on large substrates 2. The gas is channeled from the sides 30, 31 of the processing hood 1 ld into the intermediate space 32 between the two covers 28, 33. The gas flow is depicted purely schematically by means of arrows. The lateral gas distribution in the intermediate space 32 can be carried out very quickly because of the preferably freely selectable distance between the two cover plates 28, 33. The distribution of gas over the substrate 2 is ensured by the two-dimensional network of small holes 29 in the bottom cover plate 28. The free selectability of the cover distance can be obtained by means of a bottom cover 28 displaceable relative to the top cover 33 inside the processing hood 11d. Alternatively or additionally, a two-dimensional gas sparger may, of course, also be provided for the gas discharge.

The use of temporary encapsulation through the processing hood 11, 11a, 11b, 11b, 11c, 11d according to the invention enables, in contrast to EP 1 258 043, a more effective cooling of the substrate 2. With the use of permanent process boxes, a rapid cooling of the substrate 2 cannot be obtained because of the reduced convection inside the box. To prevent bending of the substrate 2, both sides of the substrate 2 must, in particular, be cooled uniformly. With a permanent box in the cooling zone, this is possible only with low rates. In the present concept, homogeneous and rapid cooling of the substrate 2 can occur through the use of tempered cooling plates and/or forced convection cooling. The latter is depicted in FIG. 8, where many individual convection coolers 35 are disposed inside a cooling chamber 34 below and above the previously tempered substrate 2. Of course, these convection coolers 35 could also be disposed inside the treatment chamber 1 for tempering; however, a separate cooling chamber 34 is preferred.

Moreover, by means of the processing hood 11, 11a, 11b, 11c, 11d that is only vertically movable but is permanently installed in the system, a more reliably defined processing environment can be ensured than with a large number of individual process boxes that are slightly different due to conventional manufacturing tolerances.

The utilization of external punctiform heat sources 10 depicted by way of example in FIG. 1 is not absolutely essential. For many applications, linear heating elements may also be used equally advantageously. These may—as proposed here for the punctiform light sources 10—be disposed outside the chamber 1. Likewise, the conventional arrangement with internal linear heaters would be compatible with the processing hood 11, 1a, 11b, 11c, 11d presented here. Similarly, instead of the large-area chamber walls 4, 5, 6, 7 transparent to electromagnetic radiation manufactured in a single piece, these may also be made up of transparent segments.

Essential to the chamber structure described here with external heating elements 10 is the sealing of the transparent chamber wall sections with the nontransparent chamber wall sections 4, 5, 6, 7. This ensures a gas-tight sealing of the toxic-gas-occupied processing space 17, 17a, 17b, 17c, 17d from the chamber space 16, 16a, 16b, 16c, 16d. To the contrary, the oxygen and water vapor level can be minimized by a purging process using inert gas (e.g., N₂) at the beginning of the process and then for the duration of the process.

The use of substrate carrier plates (or carriers) 18, on which the actual substrates 2 to be processed are placed and transported along with them through the system 1, can result from the selected implementation of substrate transport. In any case, relatively large substrates 2 necessitate mechanical support 18 during the heating process since, in the subsequent cooling process, sagging due to the weight of the substrate itself, e.g., glass, could be frozen into permanent substrate bending after the entire heating process up to the vicinity of the glass softening temperature. However, the mechanical support of the substrate 2 from below must not interfere with the homogeneous heating from below. A substrate carrier plate 18 is, however, not absolutely necessary for the processing hood 11, 11a, 11b, 11c, 11d according to the invention for the control of partial pressures and also not for the heating process according to EP 1 258 043.

FIG. 9 illustrates the transport setup 36 according to the invention for the treatment chamber 3 in the device 1 according to the invention. The transport apparatus 36 has laterally installed rollers 37 at regular intervals that support the substrate carrier 18 or the substrate 2 itself (not shown), such that it can be transported through the device.

The following optional characteristics (not shown) may be used for further advantageous improvement:

1. Metal reflectors with the radiation heaters 10 on the side turned away from the chamber.

2. Linings and coatings of the chamber space 16, 16a, 16b, 16c, 16d, that prevent cladding or corrosive attack with corrosive gases and vapors.

3. A chamber wall 4, 5, 6, 7, heated to medium-range temperatures that prevents cladding with volatile components.

4. The sequential connection of a plurality of identical or similar treatment chambers 3 of the structure depicted, whereby, after a partial processing time, the substrate 2 to be processed is rapidly moved on into the next chamber 3.

5. Introduction of two or more substrates 2 adjacent each other or sequentially into the treatment chamber 3, for which purpose either one large or a plurality of small processing hoods 11, 11a, 11b, 11c, 11d are implemented adjacent each other in one large chamber space. The simultaneous introduction of multiple substrates 2 adjacent each other or sequentially under one large or a plurality of smaller processing hoods 11, 11a, 11b, 11c, 11d is recommended when a specific cycle time is to be achieved per overall system but the process does not permit the opening of the hood 11, 11a, 11b, 11c, 11d within a specific heating phase.

6. Downstream cooling chambers 34 or a cooling zone for cooling process substrate 2.

7. Arrangements for purging gas inlet and pressure gradients according to WO 01/29901 A2.

8. Upstream vacuum introduction chambers and downstream discharge chambers to enable importing new substrates 2 and exporting the processed substrates 2 without interruption of the clean processing conditions (e.g., O₂/H₂O-concentration).

In the following, an example of a process cycle according to the invention is given. Therein, the following occur sequentially:

1. Introduction of the substrate 2 (with or without carrier 18) into a treatment chamber 3 through one or a plurality of introduction chambers.

2. Production of the required surrounding atmosphere by pumping out and/or purging.

3. Positioning of the substrate 2 beneath the first processing hood 11.

4. Lowering the processing hood 11 to produce the processing space 17 above the coated surface 15 of the substrate 2.

5. Optionally, intake of a reaction gas mixture into the processing space 17.

6. Heating the substrate 2 with desired temperature and process gas parameters by means of the radiation sources 10.

7. Raising the processing hood 11 and further transport of the substrate 2 (with or without carrier 18), whereby it is also possible to introduce two or more substrates 2 simultaneously in parallel or in sequence.

8. Optionally, the further transport mentioned in step 7 takes place into an additional treatment chamber 3 with repetition of steps 3 through 7 as well as, optionally, beforehand, of step 2.

9. Transport of the coated substrate 2 without encapsulation into a cooling zone or one or a plurality of cooling chambers 34.

10. Discharge of the coated substrate 2 through discharge chambers.

11. Further cooling of the substrate 2 to the desired final temperature.

FIGS. 10 and 11 depict, purely schematically, the two embodiments of the overall systems 40, 50, into which the device according to the invention 1 is integrated. The overall system 40 has, according to FIG. 10, a treatment zone 41 that forms the interface between the upstream and downstream process steps as well as to the processing zones. The entry door/lock 42 is provided for the production of the required surrounding/processing atmosphere. The treatment chamber 3 is used for the performance of the tempering process according to the invention. The cooling chamber 34 is used for the cooling of the substrate 2 with or without carrier 18. With the help of the exit door/lock 43, the required surrounding/processing atmosphere is produced. And finally, a transverse/return zone 44 is provided that is used for the return transport of the substrate 2 or the substrate 2 and carrier 18 into the treatment zone 41 as well as the cooling of the substrate 2 with or without carrier 18. The individual zones 41, 42, 34, 43, or 44 maybe partially or completely omitted, e.g., if the system 40 is connected to corresponding upstream or downstream systems (not shown).

In the further embodiment of the overall system 50 based on the described concept of the processing hoods 1, 11a, 11b, 11c, 11d depicted in FIG. 11, parallel processing zones 51, 51′, 51″, comprising the treatment chambers 3 and, optionally, the cooling chambers 34 for cooling, are constructed immediately after the end of the tempering process, and are loaded and unloaded from both sides via transfer chambers 52, 52′. The advantage of this arrangement is modularity, i.e., this arrangement may be extended through extension modules 53, 53′, 53″ by additional processing zones, as is discernible from the zones represented by broken lines. Furthermore, entry door/lock 54 and exit door/lock 55 are again provided, whereby another transfer chamber 52″ and an additional cooling tunnel 56 are disposed between the processing zones 51, 51′, 51″ and the exit door/lock 55.

From the preceding depictions, it has become clear that a device and a method for tempering objects that overcome the disadvantages of prior art tempering are provided, whereby, in particular, high reproducibility and high throughput of tempering are achieved with, at the same time, low investment costs, such that the process of tempering as a whole is realized very cost-effectively.

1. A device for tempering at least one object, the device comprising: a treatment chamber with a chamber space,
at least one energy source, and
a processing hood that defines a processing space in which the object can be at least partially disposed,
wherein the processing hood reduces volume of the processing space in which at least a part of the object is tempered, compared to a volume of the chamber space,
and wherein the processing hood is configured at least as a cover disposed in the treatment chamber.

2. The device according to claim 1, wherein a distance between the cover and the object is adjustable.

3. The device according to claim 1, wherein a distance between a top of the object and a bottom of the cover is smaller than 50 mm.

4. The device according to claim 1, further comprising:
at least one spacer to maintain a minimum distance between cover and the object.

5. The device according to claim 1,
wherein the cover comprises a circumferential frame to encase the object or a carrier supporting the object,
and wherein the frame is laterally displaceable relative to the object or the carrier.

6. The device according to claim 1, wherein the processing hood and the object form a gas exchange barrier, which reduces gas exchange between the processing space and the chamber space such that mass loss of material components of the object evaporated during a heating process is smaller than 50%.

7. The device according to claim 1, wherein the processing space formed by the processing hood and the object forms pressure equalization resistance relative to the chamber space.

8. The device according to claim 1, wherein the processing hood and the object are configured so that the processing space formed by the processing hood and the object is essentially gas tight.

9. The device according to claim 1, wherein the processing hood comprises an essentially circumferential zone connected with at least one gas inlet and/or gas outlet and disposed between the processing space and the chamber space relative to a gas passage direction.

10. The device according to claim 1, wherein the processing hood comprises at least one gas inlet and/or at least one gas outlet.

11. The device according to claim 1, wherein the energy source is disposed outside the chamber space.

12. The device according to claim 1, wherein the processing hood is at least partially transparent to electromagnetic radiation and/or at least one wall of the treatment chamber is at least in part at least partially transparent to electromagnetic radiation, wherein, in the wall, segments at least partially transparent to electromagnetic radiation are accommodated in a support frame.

13. The device according to claim 1, wherein at least one wall of the treatment chamber is provided with a coating and/or lining that essentially prevents cladding of the chamber wall or action of corrosive gases and vapors thereon.

14. The device according to claim 1, wherein the treatment chamber is configured to temper two or more objects simultaneously, and wherein either a common processing hood or a dedicated processing hood for each object is provided.

15. The device according to claim 1, wherein
at least two treatment chambers for tempering are disposed sequentially in the transport direction of the object and/or
at least one setup is provided for cooling the object, which setup is disposed in a cooling chamber independent of the treatment chamber.

16. The device according to claim 1, wherein a buffer space is arranged in the gas passage direction between the processing space and the chamber space,
wherein the chamber space comprises a purging gas inlet and the buffer space comprises a gas outlet,
and wherein the gas outlet out of the buffer space is adapted to discharge gas directly out of the treatment chamber, bypassing the chamber space.

17. A method for tempering at least one object in a treatment chamber with a chamber space comprising:
bringing the object into the treatment chamber exposing the object at least in part to an energy source, and
locating a processing space at least in part around the object, the processing space being smaller than the chamber space wherein the processing space is formed only in the interior of the treatment chamber.

18. The method according to claim 17, wherein the processing space is delimited from the chamber space by at least a gas exchange barrier or pressure equalization resistance.

19. The method according to claim 17, wherein a buffer space is disposed in the gas passage direction between the processing space and the chamber space and a purging gas is let into the chamber space, whereby gas pressure of the purging gas is greater than gas pressure of process gases and process reaction gases in the processing space, wherein gas possibly escaping from the buffering space is discharged by way of a gas outlet directly out of the treatment chamber, bypassing the chamber space.

20. The device according to claim 2, wherein the cover is displaceably disposed in the treatment chamber.

21. The device according to claim 4, wherein the at least one spacer is configured as a circumferential frame and rests on the object or on a carrier for the object.

22. The device according to claim 10, wherein the processing hood comprises at least one two-dimensional gas sparger.

23. The device according to claim 11, wherein the energy source is an electromagnetic radiation source.

24. The device according to claim 23, wherein the electromagnetic radiation source comprises one or more punctiform radiation sources.

25. The device according to claim 1, wherein the object is a multilayer body with at least two layers.

26. The method according to claim 17, wherein the at least one object is tempered with the device of claim 1.
